(19) United States
(12) Patent Application Publication
(10) Pub. No.: US 2008/0290354 A1
(43) Pub. Date: Nov. 27, 2008

(54) Light Emitting Diode Assembly

(75) Inventors: Christoph Gerard August Hoelen, Eindhoven (NL); Koen Van Os, Eindhoven (NL); Theodoor Cornelis Treurniet, Eindhoven (NL); Edwin Van Lier, Eindhoven (NL); Johannes Petrus Maria Ansems, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/572,582

(22) PCT Filed: Jul. 19, 2005
(86) PCT No.: PCT/IB2005/052412

§ 371 Date: Jan. 24, 2007

(30) Foreign Application Priority Data
Jul. 27, 2004 (EP) 04103584.1

(51) Int. Cl. H01L 25/075

(52) U.S. Cl. 257/90; 257/88; 257/89; 257/E33.056

(57) ABSTRACT

A light emitting diode (LED) assembly, comprising a metal substrate (1) which is partly covered on one side with a dielectric layer (2) on which an electric circuit (3) is present, and a multitude of LED units (5, 6, 7) each comprising a LED chip, wherein each LED unit is mounted in a gap in said dielectric layer on the metal substrate by a heat conducting adhesive layer (8), wherein electrical conductors (9) connect each LED unit with the electric circuit on the adjacent dielectric layer, and wherein at least two LED units are mounted together in one gap in the dielectric layer.

The invention relates to a light emitting diode (LED) assembly, comprising a metal substrate which is covered on one side with a dielectric layer on which an electric circuit is present, and a multitude of LED units each comprising a LED chip, wherein each LED unit is mounted in a gap in said dielectric layer on the metal substrate by a heat conducting adhesive layer, and wherein electrical conductors connect each LED unit with the electric circuit on the adjacent dielectric layer.

Such a LED assembly is described in U.S. Pat. No. 6,498,355. Due to the close placement of the LED units power dissipation is high and heat removal may be a problem. The LED units become too hot, which results in a strong decrease of the flux of the LED-s, in particular red LED-s. By using a heat sink, comprising a metal substrate and a heat conducting adhesive layer high power LED assemblies can be built without raising the temperature of the LED-s too much during operation. The dielectric layer is provided with a array of gaps, which are each shaped to receive a LED unit, and each LED unit is connected to the surrounding circuit on the dielectric layer, for instance by means of wires. WO 00/55925 also describes a LED assembly wherein a LED unit is mounted in a gap on an aluminium substrate by means of a heat conducting glue.

It is desirable to provide a high power multiple LED light source with minimum dimensions. This is in particular relevant for projection type lamps, such as spot lights or flood lights, where the surface area used by the LED-s determines the minimum dimensions of the optics used to shape a light beam. Also, when multiple LED-s of different colours are used to obtain for instance white light it is desirable that the light source appears to be white, instead of an array of different colours.

This object is achieved by a LED assembly according to claim 1. Preferred embodiments of the invented LED assembly are described in the dependent claims.

According to the invention at least two LED units are mounted together in one gap in the dielectric layer. In a preferred embodiment a multitude of LED units are mounted together in one gap. In this manner it is possible to place the LED-s side-by-side in a row or in an array, such that they form a more or less continuous luminous surface. Thereby the dimensions of the light source are minimised and mixing of different colours is maximised. Wires electrically connect the group of LED units with the common adjacent circuit. Each LED unit may have its own wiring to the circuit, but also a group of LED units may be interconnected by wires, such that the LED units are connected in series to the circuit.

Where the word “gap” is used, it should be understood that this does not necessarily mean that the dielectric layer completely surrounds the gap therein. In fact, according to the invention the dielectric layer and the electric circuit thereon need to be present only on one side of the array of LED units.

In a preferred embodiment LED units of different colours are mounted in one gap in the dielectric layer. During working, these LEDs emit light with mutually different wavelengths. At least one LED chip is for instance an AlInGaP chip (red, orange or yellow) and at least one other LED chip is for instance an InGaN chip (green, blue or cyan). In this manner, after mixing of the emitted light with different wavelengths, a very small white light source can be obtained, or a light source of any other desired colour.

The LED chip is preferably mounted on a silicon sub-mount by means of an electrical conducting adhesive layer, and said silicon sub-mount is mounted on the metal substrate. The silicon sub-mount therein preferably comprises an electrically insulating silicon oxide or silicon nitride layer. Silicon is known for its good thermal conductive properties. Preferably the heat conducting adhesive layer is a metal solder layer, because solder is also known as a good thermal conductive material. For the same reason, preferably the metal substrate is a copper or aluminum substrate.

The invention will be illustrated by exemplary embodiments with reference to the figures, wherein:

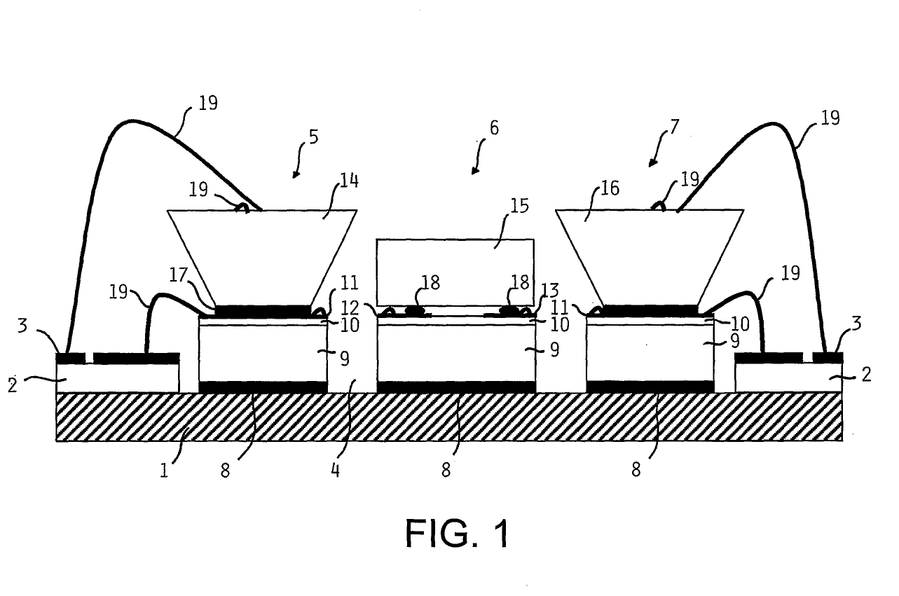

FIG. 1 is a partial cross-sectional view of a LED assembly; and

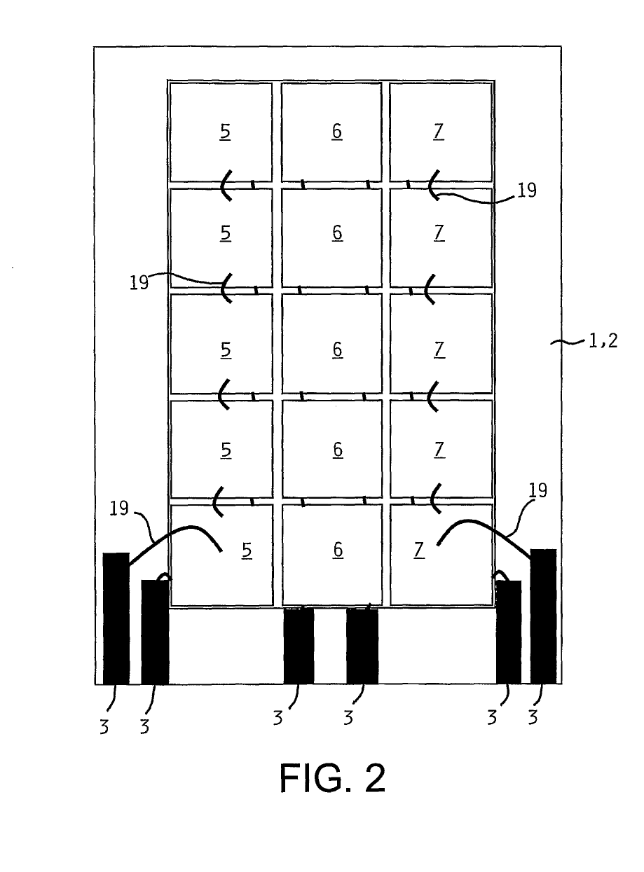

FIG. 2 is a partial top view of the LED assembly of FIG. 1.

The LED assembly comprises a copper or anodised aluminium substrate 1 provided with a dielectric layer 2 and a copper electric circuit 3. A gap 4 is provided in said layer 2, wherein fifteen LED units 5, 6, 7 are mounted directly on the substrate 1 by means of a solder layer 8. In this embodiment five rows of two AlInGaP LED units 5, 7 (for instance red and yellow) and five rows of one InGaN LED unit 6 (for instance blue) each are placed in one gap 4.

Each LED unit 5, 6, 7 comprises a silicon sub-mount 9 having an electrically insulating silicon oxide top layer 10. In the AlInGaP LED units 5, 7 the sub-mounts 9 have a metalised top surface 11, to which ALInGaP LED chips 14, 16 are attached by means of a solder layer 17. In the InGaN LED units 6 the sub-mounts 9 have two separate metalised top surface areas 12, 13, to which InGaN LED chips 15 are attached by means of separate solder bumps 18.

The LED units 5, 6, 7 are electrically connected to the surrounding electric circuit 3 and to each other by means of bond wires 19. The electrical connection of the LED chips 14, 15, 16 through the wires 19 can be done in series as shown, or alternatively each LED chip 14, 15, 16 can be individually connected through wires 19 (not shown) to the electric circuit 3.

In the shown embodiment LED units 5, 6, 7 of one colour are located in one vertical row in FIG. 2. It is also possible to alternate the LED units 5, 6, 7 of different colours in the vertical rows, similar to alternation in the horizontal rows in FIG. 2. This will result in a better mixing of the three colours.

It will be appreciated that many variations on the described embodiment will be possible within the scope of the invention.

1. A light emitting diode (LED) assembly, comprising a metal substrate (1) which is covered on one side with a dielectric layer (2) on which an electric circuit (3) is present, and a multitude of LED units (5, 6, 7) each comprising a LED chip (14, 15, 16), wherein each LED unit (5, 6, 7) is mounted in a gap (4) in said dielectric layer (2) on the metal substrate (1) by a heat conducting adhesive layer (8), and wherein electrical conductors (19) connect each LED unit with the electric circuit (3) on the adjacent dielectric layer (2), characterized in that at least two LED units (5, 6, 7) are mounted together in one gap (4) in the dielectric layer (2).

2. The LED assembly according to claim 1, wherein LED units (5, 6, 7) of different colours are mounted in one gap (4) in the dielectric layer (2).

3. The LED assembly according to claim 1, wherein the LED chip (14, 15, 16) is an AlInGaP chip and/or an InGaN chip.

4. The LED assembly according to claim 1, wherein the LED chip (14, 15, 16) is mounted on a silicon sub-mount (9) by means of an electrical conducting adhesive layer (17), and said silicon sub-mount (9) is mounted on the metal substrate (1).

5. The LED assembly according to claim 4, wherein the silicon sub-mount (9) comprises an electrically insulating silicon oxide or silicon nitride layer (10).

6. The LED assembly according to claim 1, wherein the heat conducting adhesive layer (8) is a metal solder layer.

7. The LED assembly according to claim 1, wherein the metal substrate (1) is a copper or aluminum substrate.

8. The LED assembly according to claim 1, wherein at least two LED units (5, 6, 7) are mutually interconnected by means of wires (19).
